(19) United States
(12) Patent Application Publication
(10) Pub. No.: US 2026/0141746 A1
(43) Pub. Date: May 21, 2026

(54) ELECTRONIC DEVICE

(71) Applicant: Samsung Display Co., Ltd., Yongin-Si (KR)

(72) Inventors: DAE-YOUNG LEE, Yongin-si (KR); SUJUNG HUH, Yongin-si (KR); YONGJO KIM, Yongin-si (KR); RANGKYUN MOK, Yongin-si (KR); JAEHO YOU, Yongin-si (KR); TAEHO LEE, Yongin-si (KR); HYUN SUP LEE, Yongin-si (KR)

(21) Appl. No.: 19/332,351

(22) Filed: Sep. 18, 2025

(30) Foreign Application Priority Data
Nov. 19, 2024 (KR) 10-2024-0164907

(51) Int. Cl. G06V 40/13; H10H 29/85; H10H 29/851; H10H 29/853; H10K 59/38; H10K 59/40; H10K 59/65; H10K 59/80

(52) U.S. Cl. CPC G06V 40/1318; H10H 29/8513; H10H 29/8517; H10H 29/853; H10K 59/38; H10K 59/40; H10K 59/65; H10K 59/873

(57) ABSTRACT

Disclosed is an electronic device which includes a base layer having a display area and a non-display area defined therein, a circuit layer disposed on the base layer, an element layer that is disposed on the circuit layer and that includes light emitting elements and light receiving elements disposed to correspond to the display area, and a wavelength conversion layer that is disposed on the element layer and that overlaps some of the light receiving elements.

### CROSS-REFERENCE TO RELATED APPLICATIONS

This application claims priority under 35 U.S.C. § 119 to Korean Patent Application No. 10-2024-0164907 filed on Nov. 19, 2024, in the Korean Intellectual Property Office, the disclosures of which are incorporated by reference herein in their entireties.

### BACKGROUND

Embodiments of the present disclosure described herein relate to an electronic device having a biometric information recognition function.

An electronic device provides various functions that enable a user to interact with the electronic device. For example, the electronic device may display an image to provide information to the user or may sense a user input. Recent electronic devices include a function for sensing biometric information of a user.

The biometric information may be recognized using a capacitive sensing technique for sensing a change in capacitance between electrodes, a light sensing technique for sensing incident light using an optical sensor, or an ultrasonic sensing technique for sensing vibration using a piezoelectric element.

### SUMMARY

Embodiments of the present disclosure provide an electronic device for recognizing various pieces of biometric information.

According to an embodiment, an electronic device includes a base layer having a display area and a non-display area, a circuit layer disposed on the base layer, an element layer that is disposed on the circuit layer and that includes light emitting elements and light receiving elements disposed in the display area, and a wavelength conversion layer that is disposed on the element layer and that overlaps some of the light receiving elements.

According to an embodiment, an electronic device includes a base layer having a display area and a non-display area, a circuit layer disposed on the base layer, an element layer that is disposed on the circuit layer and that includes a first light emitting element, a second light emitting element, a first light receiving element, and a second light receiving element disposed in the display area, a color filter layer that is disposed on the element layer and that includes a first color filter and a second color filter that overlap the first light emitting element and the second light emitting element, respectively, and a first dummy color filter and a second dummy color filter that overlap the first light receiving element and the second light receiving element, respectively, and a wavelength conversion layer disposed between the second light receiving element and the second dummy color filter.

### BRIEF DESCRIPTION OF THE DRAWINGS

The above and other objects and features of the present disclosure will become

apparent by describing in detail embodiments thereof with reference to the accompanying drawings.

FIG. 1 is a perspective view of an electronic device according to an embodiment of the present disclosure.

FIG. 2A is an exploded perspective view of the electronic device according to an embodiment of the present disclosure.

FIG. 2B is a sectional view of the electronic device according to an embodiment of the present disclosure.

FIG. 3 is a plan view of a display panel according to an embodiment of the present disclosure.

FIG. 4 is a sectional view illustrating a portion of the electronic device according to an embodiment of the present disclosure.

FIG. 5A is a view illustrating a first sensing operation of the electronic device according to an embodiment of the present disclosure.

FIG. 5B is a view illustrating a second sensing operation of the electronic device according to an embodiment of the present disclosure.

FIG. 6 is a sectional view illustrating a portion of the electronic device according to an embodiment of the present disclosure.

FIG. 7A is a view illustrating a wavelength conversion layer according to an embodiment of the present disclosure.

FIG. 7B is a view illustrating a wavelength conversion layer according to an embodiment of the present disclosure.

FIG. 8 is a view illustrating the pitch of chiral liquid crystals included in a liquid crystal layer according to an embodiment of the present disclosure.

FIG. 9A is a plan view illustrating an arrangement relationship between light emitting elements, light receiving elements, and a wavelength conversion layer according to an embodiment of the present disclosure.

FIG. 9B is a plan view illustrating an arrangement relationship between light emitting elements, light receiving elements, and a wavelength conversion layer according to an embodiment of the present disclosure.

FIG. 10 is a block diagram of an electronic device according to an embodiment of the present disclosure.

FIG. 11 illustrates schematic views of electronic devices according to various embodiments.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure will be described with reference to the accompanying drawings.

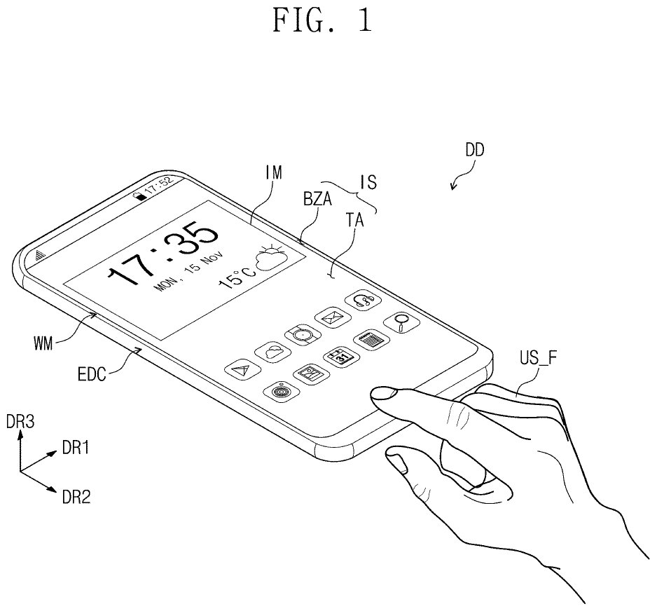

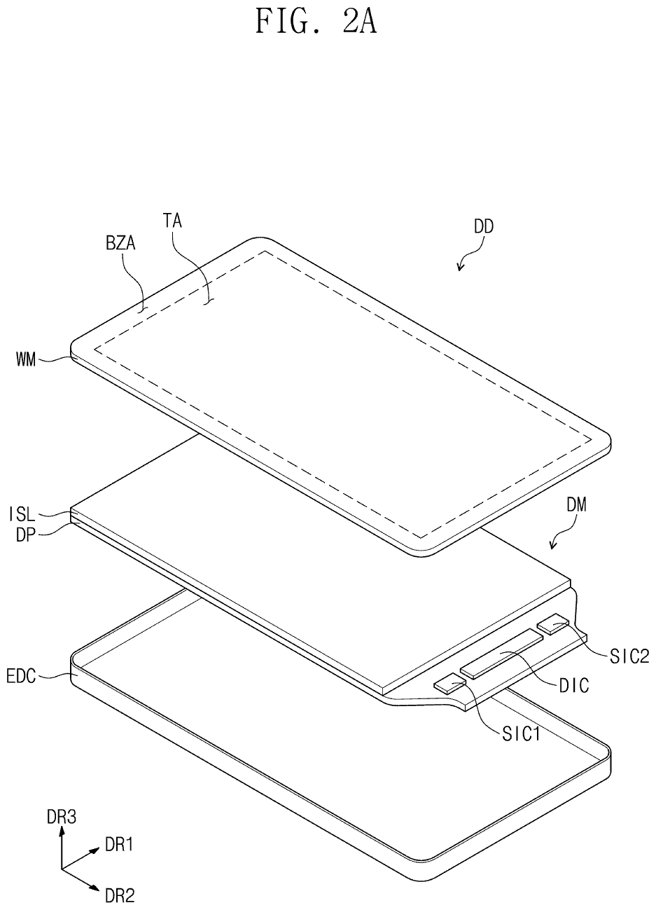

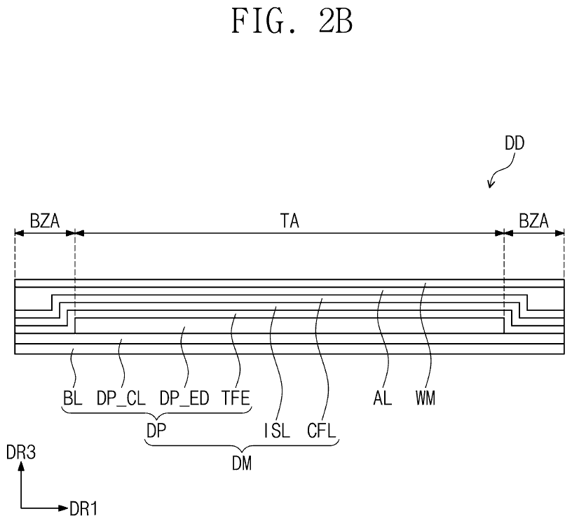

FIG. 1 is a perspective view of an electronic device according to an embodiment of the present disclosure. FIG. 2A is an exploded perspective view of the electronic device according to an embodiment of the present disclosure. FIG. 2B is a sectional view of the electronic device according to an embodiment of the present disclosure.

Referring to FIGS. 1, 2A, and 2B, the electronic device DD according to an embodiment of the present disclosure may have a rectangular shape with short sides parallel to a first direction DR1 and long sides parallel to a second direction DR2 crossing the first direction DR1. However, without being limited thereto, the electronic device DD may have various shapes such as a circular shape, a polygonal shape, and the like.

The electronic device DD may be a device activated in response to an electrical signal. The electronic device DD may include various embodiments. For example, the electronic device DD may be applied to electronic devices such as a smart watch, a tablet computer, a notebook computer, a computer, a smart television, and the like.

Hereinafter, a normal direction substantially perpendicular to a plane defined by the first direction DR1 and the second direction DR2 is defined as a third direction DR3. The expression “when viewed from above the plane” used herein may mean that it is viewed in the third direction DR3.

The upper surface of the electronic device DD may be defined as a display surface IS and may be parallel to the plane defined by the first direction DR1 and the second direction DR2. Images IM generated by the electronic device DD may be provided to a user through the display surface IS.

The display surface IS may be divided into a transmissive area TA and a bezel area BZA. The transmissive area TA may be an area on which the images IM are displayed. The user visually recognizes the images IM through the transmissive area TA. In this embodiment, the transmissive area TA is illustrated in a rounded rectangular shape. However, this is illustrative, and the transmissive area TA may have various shapes and is not limited to any one embodiment.

The bezel area BZA is adjacent to the transmissive area TA. The bezel area BZA may have a certain color. The bezel area BZA may surround the transmissive area TA. Accordingly, the shape of the transmissive area TA may be substantially defined by the bezel area BZA. However, this is illustrative, and the bezel area BZA may be disposed adjacent to only one side of the transmissive area TA or may be omitted.

The electronic device DD may sense an external input applied from the outside. The external input may include various types of inputs provided from outside the electronic device DD. For example, the external input may include not only contact by a part of the user's body such as the user's hand US_F or contact by a separate device (e.g., an active pen or a digitizer) but also an external input (e.g., hovering) that is applied in proximity to the electronic device DD or applied adjacent to the electronic device DD at a certain distance. In addition, the external input may have various forms such as force, pressure, temperature, light, and the like.

The electronic device DD may sense the user's biometric information applied from the outside. A biometric information sensing area capable of sensing the user's biometric information may be provided on the display surface IS of the electronic device DD. The biometric information sensing area may be provided in the entire transmissive area TA or may be provided in a partial region of the transmissive area TA. FIG. 1 illustrates an example of an entire transmissive area TA used as the biometric information sensing area.

The electronic device DD may include a window WM, a display module DM, and a housing EDC. In this embodiment, the window WM and the housing EDC are coupled with each other to form the exterior of the electronic device DD.

The front surface of the window WM defines the display surface IS of the electronic device DD. The window WM may include an optically clear insulating material. For example, the window WM may include glass or plastic. The window WM may have a multi-layer structure or a single-layer structure. For example, the window WM may include a plurality of plastic films coupled through an adhesive or may include a glass substrate and a plastic film coupled through an adhesive.

The display module DM may include a display panel DP and an input sensing layer ISL. The display panel DP may display an image in response to an electrical signal, and the input sensing layer ISL may sense an external input applied from the outside. The external input may be provided in various forms.

The display panel DP according to an embodiment of the present disclosure may be an emissive display panel, but is not particularly limited. For example, the display panel DP may be an organic light emitting display panel, an inorganic light emitting display panel, or a quantum-dot light emitting display panel. An emissive layer of the organic light emitting display panel may include an organic luminescent material, and an emissive layer of the inorganic light emitting display panel may include an inorganic luminescent material. An emissive layer of the quantum-dot light emitting display panel may include quantum dots and quantum rods. Hereinafter, it will be exemplified that the display panel DP is an organic light emitting display panel.

Referring to FIG. 2B, the display panel DP includes a base layer BL, a circuit layer DP_CL, an element layer DP_ED, and an encapsulation layer TFE. The display panel DP according to the present disclosure may be a flexible display panel. However, the present disclosure is not limited thereto. For example, the display panel DP may be a foldable display panel that is folded about a folding axis or may be a rigid display panel.

The base layer BL may include a synthetic resin layer. The synthetic resin layer may be a polyimide-based resin layer, and the material thereof is not particularly limited. In addition, the base layer BL may include a glass substrate, a metal substrate, or an organic/inorganic composite substrate.

The circuit layer DP_CL is disposed on the base layer BL. The circuit layer DP_CL is disposed between the base layer BS and the element layer DP_ED. The circuit layer DP_CL includes at least one insulating layer and a circuit element. Hereinafter, the insulating layer included in the circuit layer DP_CL is referred to as an intermediate insulating layer. The intermediate insulating layer includes at least one intermediate inorganic film and at least one intermediate organic film. The circuit element may include a pixel drive circuit included in each of a plurality of pixels for displaying an image and a sensor drive circuit included in each of a plurality of sensors for recognizing external information. The external information may be biometric information. In an embodiment of the present disclosure, the sensor may be a fingerprint recognition sensor, a proximity sensor, an iris recognition sensor, an oxygen saturation sensor, a blood pressure measurement sensor, an illuminance sensor, or the like. In an embodiment, the sensor may be an optical sensor for optically recognizing biometric information. The circuit layer DP_CL may further include signal lines connected to the pixel drive circuit and/or the sensor drive circuit.

The element layer DP_ED may include a light emitting element included in each of the pixels and a light receiving element included in each of the sensors. In an embodiment of the present disclosure, the light receiving element may be a photo diode. The light receiving element may be a sensor that senses, or reacts to, light reflected by the user's fingerprint or blood flow.

The encapsulation layer TFE seals the element layer DP_ED. The encapsulation layer TFE may include at least one organic film and at least one inorganic film. The inorganic film may include an inorganic material and may protect the element layer DP_ED from moisture/oxygen. The inorganic film may include a silicon nitride layer, a silicon oxy nitride layer, a silicon oxide layer, a titanium oxide layer, or an aluminum oxide layer, but is not particularly limited thereto. The organic film may include an organic material and may protect the element layer DP_ED from foreign matter such as dust particles.

The input sensing layer ISL may be formed on the display panel DP. The input sensing layer ISL may be directly disposed on the encapsulation layer TFE. According to an embodiment of the present disclosure, the input sensing layer ISL may be formed on the display panel DP by a continuous process. That is, when the input sensing layer ISL is directly disposed on the display panel DP, an adhesive film is not disposed between the input sensing layer ISL and the encapsulation layer TFE. In an embodiment, an adhesive film may be disposed between the input sensing layer ISL and the display panel DP. In this case, the input sensing layer ISL may not be manufactured on the display panel DP by the continuous process and may be manufactured separately from the display panel DP and fixed to the upper surface of the display panel DP by the adhesive film.

The input sensing layer ISL may sense an external input (e.g., the user's touch), may change the sensed external input into a certain input signal, and may provide the input signal to the display panel DP. The input sensing layer ISL may include a plurality of sensing electrodes for sensing the external input. The sensing electrodes may sense the external input in a capacitance type. The display panel DP may receive the input signal from the input sensing layer ISL and may generate an image corresponding to the input signal.

The display module DM may further include a color filter layer CFL. In an embodiment of the present disclosure, the color filter layer CFL may be disposed on the input sensing layer ISL. However, the present disclosure is not limited thereto. The color filter layer CFL may be disposed between the display panel DP and the input sensing layer ISL. The color filter layer CFL may include a plurality of color filters and a black matrix.

The structures of the input sensing layer ISL and the color filter layer CFL will be described below in detail.

The electronic device DD according to an embodiment of the present disclosure may further include an adhesive layer AL. The window WM may be attached to the color filter layer CFL by the adhesive layer AL. The adhesive layer AL may include an optically clear adhesive, an optically clear adhesive resin, or a pressure sensitive adhesive (PSA).

The display module DM may further include a driver chip DIC and sensor chips SIC1 and SIC2. In an embodiment of the present disclosure, the driver chip DIC and the sensor chips SIC1 and SIC2 may be mounted on the display panel DP. The driver chip DIC and the sensor chips SIC1 and SIC2 may be disposed adjacent to one end portion (hereinafter, referred to as the first end portion) of the display panel DP. Although FIG. 2A illustrates the structure in which the driver chip DIC and the sensor chips SIC1 and SIC2 are disposed adjacent to the first end portion of the display panel DP, the present disclosure is not limited thereto. For example, the driver chip DIC may be disposed adjacent to the first end portion of the display panel DP, and the sensor chips SIC1 and SIC2 may be disposed adjacent to a second end portion of the display panel DP that faces away from the first end portion.

In an embodiment of the present disclosure, the sensor chips SIC1 and SIC2 may include the first sensor chip SIC1 disposed on one side (hereinafter, referred to as the first side) of the driver chip DIC and the second sensor chip SIC2 disposed on a second side of the driver chip DIC that is different from the first side. However, in an embodiment, the first sensor chip SIC1 and the second sensor chip SIC2 may be integrated into one sensor chip, and the one sensor chip may be disposed adjacent to the driver chip DIC. In the present disclosure, the number of sensor chips SIC1 and SIC2 and the number of driver chips DIC are not particularly limited.

The housing EDC is coupled with the window WM. The housing EDC coupled with the window WM provides a certain inner space. The display module DM may be accommodated in the inner space. The housing EDC may include a material having a relatively high rigidity. For example, the housing EDC may include glass, plastic, or metal or may include a plurality of frames and/or plates formed of a combination thereof. The housing EDC may stably protect components of the electronic device DD accommodated in the inner space from external impact. Although not illustrated, a battery module for supplying power for overall operation of the electronic device DD may be disposed between the display module DM and the housing EDC.

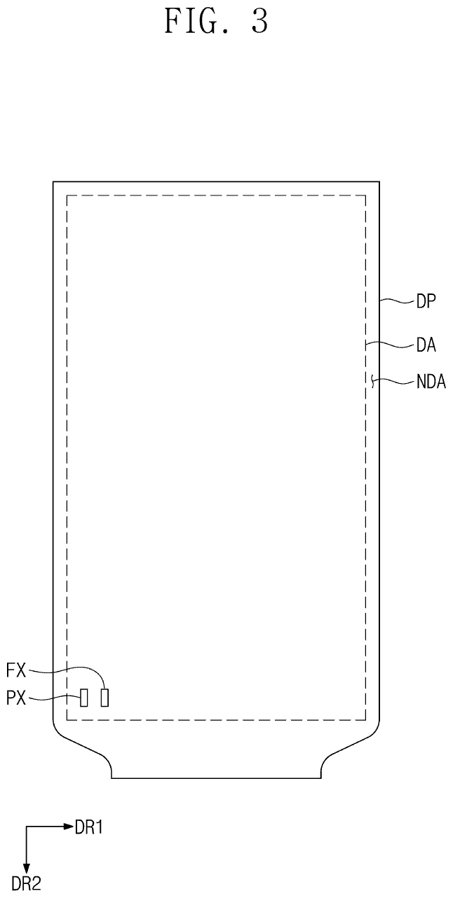

FIG. 3 is a plan view of the display panel according to an embodiment of the present disclosure.

Referring to FIG. 3, the display panel DP may include a display area DA corresponding to the transmissive area TA (illustrated in FIG. 1) and a non-display area NDA corresponding to the bezel area BZA (illustrated in FIG. 1).

The display panel DP may include a plurality of pixels PX disposed in the display area DA and a plurality of sensors FX disposed in the display area DA. In an embodiment of the present disclosure, each of the plurality of sensors FX may be disposed between two pixels PX adjacent to each other. The plurality of pixels PX and the plurality of sensors FX may alternate with one another in the first direction DR1 and the second direction DR2. However, the present disclosure is not limited thereto. That is, two or more pixels PX may be disposed between two sensors FX adjacent to each other in the first direction DR1 among the plurality of sensors FX, or two or more pixels PX may be disposed between two sensors FX adjacent to each other in the second direction DR2 among the plurality of sensors FX.

The display panel DP may further include signal lines connected to the pixels PX and the sensors FX. The signal lines may include scan lines, data lines, readout lines, and voltage lines.

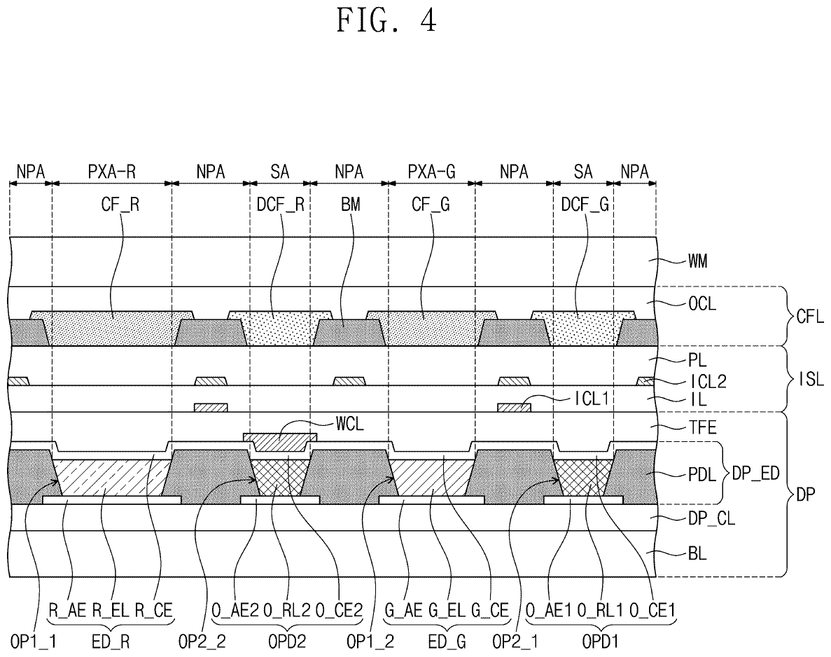

FIG. 4 is a sectional view illustrating a portion of the electronic device according to an embodiment of the present disclosure.

Referring to FIG. 4, the display panel DP may include the base layer BL, the circuit layer DP_CL, and the element layer DP_ED.

The base layer BL may include a synthetic resin layer. The synthetic resin layer may include a thermosetting resin. In particular, the synthetic resin layer may be a polyimide-based resin layer, and the material thereof is not particularly limited. The synthetic resin layer may include at least one of an acrylic resin, a methacrylic resin, a polyisoprene resin, a vinyl resin, an epoxy resin, a urethane-based resin, a cellulosic resin, a siloxane-based resin, a polyamide resin, or a perylene-based resin. In addition, the base layer BL may include a glass substrate, a metal substrate, or an organic/inorganic composite substrate.

At least one inorganic layer is formed on the upper surface of the base layer BL. The inorganic layer may include at least one of aluminum oxide, titanium oxide, silicon oxide, silicon oxy nitride, zirconium oxide, or hafnium oxide. The inorganic layer may be formed of multiple layers.

A first electrode layer is disposed on the circuit layer DP_CL. A pixel defining layer PDL is formed on the first electrode layer. The first electrode layer may include a red anode electrode R_AE and a green anode electrode G_AE. The first electrode layer may further include a blue anode electrode. A first light emitting opening OP1_1 and a second light emitting opening OP1_2 of the pixel defining layer PDL expose at least a portion of the red anode electrodes R_AE and at least a portion of the green anode electrode G_AE, respectively. A third light emitting opening of the pixel defining layer PDL may expose the blue anode electrode.

In an embodiment of the present disclosure, the pixel defining layer PDL may further include a black material. The pixel defining layer PDL may further include a black organic dye/pigment such as carbon black, aniline black, or the like. The pixel defining layer PDL may be formed by mixing a blue organic material and a black organic material. The pixel defining layer PDL may further include a liquid-repellent organic material.

As illustrated in FIG. 4, the display panel DP may include a first emissive area PXA-R, a second emissive area PXA-G, and a non-emissive area NPA adjacent to the first emissive area PXA-R and the second emissive area PXA-G. The non-emissive area NPA may surround the corresponding emissive areas PXA-R and PXA-G. In this embodiment, the first emissive area PXA-R is defined to correspond to a partial region of the red anode electrode R_AE exposed by the first light emitting opening OP1_1. The second emissive area PXA-G is defined to correspond to a partial region of the green anode electrode G_AE exposed by the second light emitting opening OP1_2. The display panel DP further includes a third emissive area, and the third emissive area is defined to correspond to a partial region of the blue anode electrode exposed by the third light emitting opening.

An emissive layer may be disposed on the first electrode layer. The emissive layer may include a red emissive layer R_EL and a green emissive layer G_EL. The red emissive layer R_EL may be disposed in the area corresponding to the first light emitting opening OP1_1, and the green emissive layer G_EL may be disposed in the area corresponding to the second light emitting opening OP1_2. The emissive layer further includes a blue emissive layer disposed on the blue anode electrode in correspondence to the third light emitting opening. The red emissive layer R_EL, the green emissive layer G_EL, and the blue emissive layer may be formed to be separated from one another. Each of the red emissive layer R_EL, the green emissive layer G_EL, and the blue emissive layer may include an organic material and/or an inorganic material. The red emissive layer R_EL, the green emissive layer G_EL, and the blue emissive layer may generate light of certain colors. For example, the red emissive layer R_EL may generate red light, the green emissive layer G_EL may generate green light, and the blue emissive layer may generate blue light.

Although the patterned red and green emissive layers R_EL and G_EL are illustrated in this embodiment, one emissive layer may be commonly disposed in the first emissive area PXA-R, the second emissive area PXA-G, and the third emissive area. In this case, the emissive layer may generate white light or blue light. In addition, the emissive layer may have a multi-layer structure called tandem.

Each of the red and green emissive layers R_EL and G_EL may include a low molecular weight organic material or a high molecular weight organic material as a luminescent material. In an embodiment, each of the red and green emissive layers R_EL and G_EL may include a quantum-dot material as a luminescent material. A core of a quantum dot may be selected from Group II-VI compounds, Group III-V compounds, Group IV-VI compounds, Group IV elements, Group IV compounds, and combinations thereof.

A second electrode layer is disposed on the red emissive layer R_EL, the green emissive layer G_EL, and the blue emissive layer. The second electrode layer may include a red cathode electrode R_CE and a green cathode electrode G_CE. The red and green cathode electrodes R_CE and G_CE may be electrically connected with each other. In an embodiment of the present disclosure, the red and green cathode electrodes R_CE and G_CE may be combined into a single body shape. In this case, the red and green cathode electrodes R_CE and G_CE may be commonly disposed in the first emissive area PXA-R, the second emissive area PXA-G, and the non-emissive area NPA.

The element layer DP_ED may further include a first light receiving element OPD1 and a second light receiving element OPD2. Each of the first light receiving element OPD1 and the second light receiving element OPD2 may be a photo diode. The pixel defining layer PDL may further include a first light receiving opening OP2_1 and a second light receiving opening OP2_2 provided to correspond to the first light receiving element OPD1 and the second light receiving element OPD2. The display panel DP may further include sensing areas SA that correspond to the first light receiving element OPD1 and the second light receiving element OPD2. The non-emissive area NPXA may surround the sensing areas SA.

The first light receiving element OPD1 may include a first sensing anode electrode O_AE1, a first photoelectric conversion layer O_RL1, and a first sensing cathode electrode O_CE1. The second light receiving element OPD2 may include a second sensing anode electrode O_AE2, a second photoelectric conversion layer O_RL2, and a second sensing cathode electrode O_CE2. The first sensing anode electrode O_AE1 and the second sensing anode electrode O_AE2 may be disposed on the same layer as the first electrode layer. That is, the first sensing anode electrode O_AE1 and the second sensing anode electrode O_AE2 may be disposed on the circuit layer DP_CL and may be simultaneously formed through the same process as the red and green anode electrodes R_AE and G_AE.

The first light receiving opening OP2_1 and the second light receiving opening OP2_2 of the pixel defining layer PDL expose at least a portion of the first sensing anode electrode O_AE1 and at least a portion of the second sensing anode electrode O_AE2, respectively. The first photoelectric conversion layer O_RL1 is disposed on the first sensing anode electrode O_AE1 exposed by the first light receiving opening OP2_1, and the second photoelectric conversion layer O_RL2 is disposed on the second sensing anode electrode O_AE2 exposed by the second light receiving opening OP2_2. The first photoelectric conversion layer O_RL1 and the second photoelectric conversion layer O_RL2 may include an organic photo sensing material. The first photoelectric conversion layer O_RL1 and the second photoelectric conversion layer O_RL2 may include a photo sensing material that reacts to light in the same wavelength band (e.g., green light).

The first sensing cathode electrode O_CE1 may be disposed on the first photoelectric conversion layer O_RL1, and the second sensing cathode electrode O_CE2 may be disposed on the second photoelectric conversion layer O_RL2. The first sensing cathode electrode O_CE1 and the second sensing cathode electrode O_CE2 may be simultaneously formed through the same process as the red and green cathode electrodes R_CE and G_CE. In an embodiment of the present disclosure, the first sensing cathode electrode O_CE1 and the second sensing cathode electrode O_CE2 may be combined into a single body shape with the red and green cathode electrodes R_CE and G_CE to form a common cathode electrode.

The element layer DP_ED may further include a wavelength conversion layer WCL. The wavelength conversion layer WCL is disposed on the second sensing cathode electrode O_CE2. That is, the wavelength conversion layer WCL may be disposed on the common cathode electrode to correspond to the second light receiving element OPD2. When viewed from above the plane, the wavelength conversion layer WCL may overlap the second light receiving element OPD2 and may not overlap the first light receiving element OPD1.

In an embodiment of the present disclosure, the wavelength conversion layer WCL may be formed on the common cathode electrode through a photolithography process.

The encapsulation layer TFE is disposed on the element layer DP_ED. The wavelength conversion layer WCL and the common cathode electrode may be covered by the encapsulation layer TFE. The encapsulation layer TFE includes at least an inorganic layer or an organic layer. In an embodiment of the present disclosure, the encapsulation layer TFE may include two inorganic layers and an organic layer disposed therebetween. In an embodiment of the present disclosure, the encapsulation layer TFE may include a plurality of inorganic layers and a plurality of organic layers alternately stacked one above another.

The inorganic layer protects the red and green light emitting elements ED_R and ED_G, the first light receiving element OPD1, and the second light receiving element OPD2 from moisture/oxygen, and the organic layer protects the red and green light emitting elements ED_R and ED_G, the first light receiving element OPD1, and the second light receiving element OPD2 from foreign matter such as dust particles. The inorganic layer may include a silicon nitride layer, a silicon oxy nitride layer, a silicon oxide layer, a titanium oxide layer, or an aluminum oxide layer, but is not particularly limited thereto. The organic layer may include an acrylic organic layer, but is not particularly limited.

The electronic device DD includes the input sensing layer ISL disposed on the display panel DP and the color filter layer CFL disposed on the input sensing layer ISL.

The input sensing layer ISL may be directly disposed on the encapsulation layer TFE. The input sensing layer ISL includes a first conductive layer ICL1, an insulating layer IL, a second conductive layer ICL2, and a protective layer PL. The first conductive layer ICL1 may be disposed on the encapsulation layer TFE. Although FIG. 4 illustrates the structure in which the first conductive layer ICL1 is directly disposed on the encapsulation layer TFE, the present disclosure is not limited thereto. The input sensing layer ISL may further include a base insulating layer disposed between the first conductive layer ICL1 and the encapsulation layer TFE. In this case, the encapsulation layer TFE may be covered by the base insulating layer, and the first conductive layer ICL1 may be disposed on the base insulating layer. In an embodiment of the present disclosure, the base insulating layer may include an inorganic insulating material.

The insulating layer IL may cover the first conductive layer ICL1. The second conductive layer ICL2 is disposed on the insulating layer IL. Although FIG. 4 illustrates the structure in which the input sensing layer ISL includes the first conductive layer ICL1 and the second conductive layer ICL2, the present disclosure is not limited thereto. For example, the input sensing layer ISL may include only one of the first conductive layer ICL1 and the second conductive layer ICL2.

The protective layer PL may be disposed on the second conductive layer ICL2. The protective layer PL may include an organic insulating material. The protective layer PL may serve to protect the first conductive layer ICL1 and the second conductive layer ICL2 from moisture/oxygen and may serve to protect the first conductive layer ICL1 and the second conductive layer ICL2 from foreign matter.

The color filter layer CFL may be disposed on the input sensing layer ISL. The color filter layer CFL may be directly disposed on the protective layer PL. The color filter layer CFL may include a first color filter CF_R and a second color filter CF_G. The first color filter CF_R has a first color, and the second color filter CF_G has a second color. The first color filter CF_R overlaps the first light emitting element ED_R, and the second color filter CF_G overlaps the second light emitting element ED_G. The color filter layer CFL may further include a third color filter that overlaps the third light emitting element and has a third color. In an embodiment of the present disclosure, the first color may be red, the second color may be green, and the third color may be blue.

The color filter layer CFL may further include a first dummy color filter DCF_G and a second dummy color filter DCF_R. The first dummy color filter DCF_G and the second dummy color filter DCF_R may overlap the sensing areas SA. When viewed from above the plane, the first dummy color filter DCF_G may overlap the first light receiving element OPD1, and the second dummy color filter DCF_R may overlap the second light receiving element OPD2. In an embodiment of the present disclosure, each of the first dummy color filter DCF_G and the second dummy color filter DCF_R may have the same color as one of the first color filter CF_R, the second color filter CF_G, and the third color filter. In an embodiment of the present disclosure, the first dummy color filter DCF_G may have the same green color as the second color filter CF_G, and the second dummy color filter DCF_R may have the same red color as the first color filter CF_R.

The color filter layer CFL may further include a black matrix BM. The black matrix BM may be disposed to correspond to the non-emissive area NPA. The black matrix BM may be disposed to overlap the first conductive layer ICL1 and the second conductive layer ICL2 in the non-emissive area NPA. In an embodiment of the present disclosure, the black matrix BM may not overlap the first emissive area PXA-R, the second emissive area PXA-G, and the sensing areas SA.

In an embodiment of the present disclosure, the wavelength conversion layer WCL may be disposed between the second dummy color filter DCF_R and the second light receiving element OPD2. Accordingly, the wavelength conversion layer WCL may convert the wavelength of light passing through the second dummy color filter DCF_R and may provide the converted light to the second light receiving element OPD2. When the second light receiving element OPD2 is a green-type light receiving element that senses light in the green wavelength band, the wavelength conversion layer WCL may convert light in the red wavelength band that passes through the second dummy color filter DCF_R into light in the green wavelength band.

The color filter layer CFL may further include an overcoating layer OCL. The overcoating layer OCL may include an organic insulating material. The overcoating layer OCL may have a thickness sufficient to remove steps between the first and second color filters CF_R and CF_G, the first and second dummy color filters DCF_G and DCF_R, and the black matrix BM. Without any specific limitation, the overcoating layer OCL may include any material that has a certain thickness and is capable of flattening the upper surface of the color filter layer CFL. For example, the overcoating layer OCL may include an acrylic organic material.

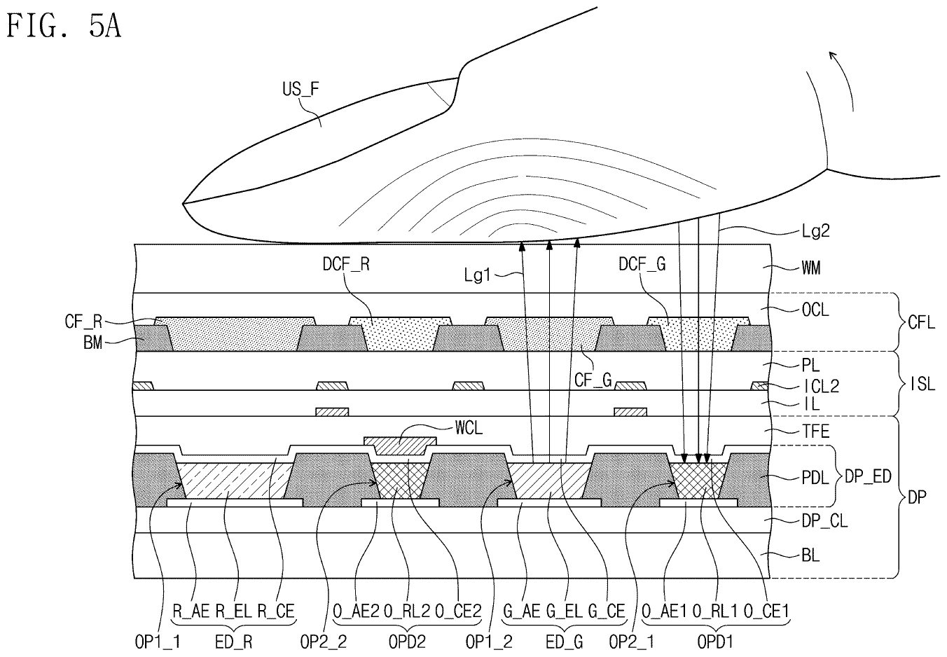

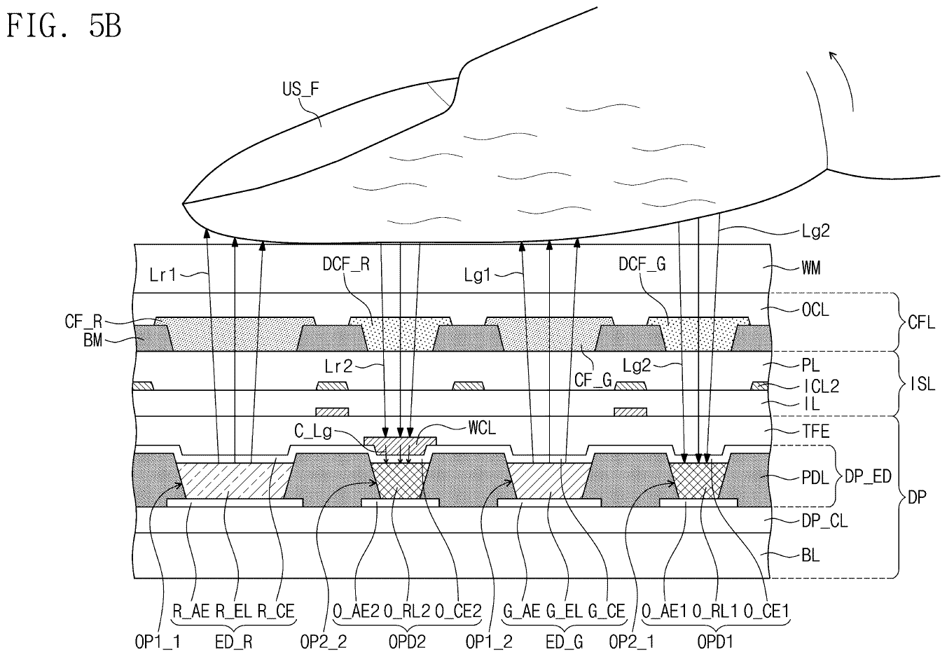

FIG. 5A is a view illustrating a first sensing operation of the electronic device according to an embodiment of the present disclosure, and FIG. 5B is a view illustrating a second sensing operation of the electronic device according to an embodiment of the present disclosure.

Referring to FIGS. 5A and 5B, when the electronic device DD (refer to FIG. 1) operates, each of the red and green light emitting elements ED_R and ED_G may output light. The red light emitting element ED_R (referred to as a second light emitting element) emits red light Lr1 (referred to as second light) in the red wavelength band, and the green light emitting element ED_G (referred to as a first light emitting element) emits green light Lg1 (referred to as first light) in the green wavelength band. In an embodiment of the present disclosure, each of the first light receiving element OPD1 and the second light receiving element OPD2 may be a green-type light receiving element that senses light in the green wavelength band. That is, the first light receiving element OPD1 and the second light receiving element OPD2 may be light receiving elements of the same type.

When the electronic device DD performs the first sensing operation to sense the user's fingerprint (that is, when the electronic device DD operates in a fingerprint sensing mode (or, a first sensing mode)), the first light receiving element OPD1 may receive first reflected light Lg2 generated by the reflection of the green light Lg1, which is output from the green light emitting element ED_G, by the user's fingerprint. In the fingerprint sensing mode, the first light receiving element OPD1 may operate (may be activated), and the second light receiving element OPD2 may not operate (may be deactivated).

The first reflected light Lg2 may be light in the green wavelength band. The first dummy color filter DCF_G is disposed over the first light receiving element OPD1. The first dummy color filter DCF_G may be green in color. Accordingly, the first reflected light Lg2 may pass through the first dummy color filter DCF_G and may be incident to the first light receiving element OPD1. The electronic device DD may sense the valleys and ridges of the fingerprint based on the intensity of the first reflected light Lg2 sensed through the first light receiving element OPD1.

In the fingerprint sensing mode, the red light Lr1 output from the red light emitting element ED_R may also be reflected by the user's hand US_F. For example, when light generated by the reflection of the red light Lr1, which is output from the red light emitting element ED_R, by the user's hand US_F is defined as second reflected light Lr2, the second reflected light Lr2 may fail to pass through the first dummy color filter DCF_G and may be absorbed by the first dummy color filer DCF_G. Accordingly, the second reflected light Lr2 is not able to be incident to the first light receiving element OPD1 because second reflected light Lr2 fails to pass through the first dummy color filter DCF_G. Likewise, even though blue light is reflected by the user's hand US_F, blue light may be absorbed by the first dummy color filter DCF_G. Accordingly, only first reflected light Lg2 may be provided to the first light receiving element OPD1.

Since the second light receiving element OPD2 is in the deactivated state in the fingerprint sensing mode, light incident to the second light receiving element OPD2 is not able to be used to sense the fingerprint.

When the electronic device DD performs the second sensing operation to sense the user's oxygen saturation (that is, when the electronic device DD operates in an oxygen saturation sensing mode (or, a second sensing mode)), both the first light receiving element OPD1 and the second light receiving element OPD2 may be activated. The oxygen saturation is the ratio of oxygenated hemoglobin (HbO₂) to total hemoglobin (Hb) in the blood. The oxygenated hemoglobin (HbO₂) has a high light absorption rate at 530 nm, 585 nm, and 900 nm, and the hemoglobin (Hb) has a high light absorption rate at 685 nm. That is, in the red wavelength band, the hemoglobin Hb has a higher light absorption rate than the oxygenated hemoglobin. Accordingly, light in the green wavelength band and light in the red wavelength band may be used to measure the oxygen saturation.

In the oxygen saturation sensing mode, the first light receiving element OPD1 may receive the first reflected light Lg2 that is generated by the reflection of the green light Lg1, which is output from the green light emitting element ED_G, by the user's blood. The first reflected light Lg2 may be light in the green wavelength band. The first dummy color filter DCF_G is disposed over the first light receiving element OPD1. The first reflected light Lg2 may pass through the first dummy color filter DCF_G and may be incident to the first light receiving element OPD1.

In the oxygen saturation sensing mode, the second reflected light Lr2 generated by the reflection of the red light Lr1, which is output from the red light emitting element ED_R, by the user's blood may be incident to the second dummy color filter DCF_R. The second reflected light Lr2 may be light in the red wavelength band, and the second dummy color filter DCF_R may be red in color. Accordingly, the second reflected light Lr2 is incident to the wavelength conversion layer WCL after passing through the second dummy color filter DCF_R. The wavelength conversion layer WCL converts the wavelength of the second reflected light Lr2 and outputs first converted light C_Lg. In an embodiment of the present disclosure, the first converted light C_Lg may be light in the green wavelength band. The first converted light C_Lg may be incident to the second light receiving element OPD2.

In the oxygen saturation sensing mode, the electronic device DD may sense the oxygen saturation, based on the ratio between the intensity of the first reflected light Lg2 sensed through the first light receiving element OPD1 and the intensity of the first converted light C_Lg sensed through the second light receiving element OPD2.

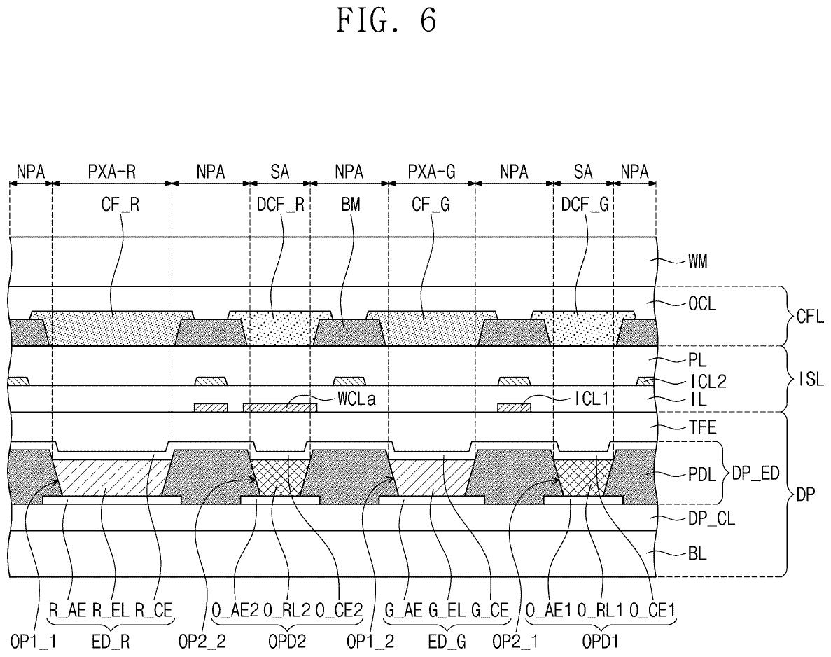

FIG. 6 is a sectional view illustrating a portion of the electronic device according to an embodiment of the present disclosure. Among the components illustrated in FIG. 6, components identical to the components illustrated in FIG. 4 will be assigned with identical reference numerals, and detailed description thereof will be omitted.

Referring to FIG. 6, a wavelength conversion layer WCLa may be disposed between the second dummy color filter DCF_R and the second light receiving element OPD2. In particular, the wavelength conversion layer WCLa may be disposed on the encapsulation layer TFE.

Although FIG. 6 illustrates the structure in which the wavelength conversion layer WCLa is disposed on the same layer as the first conductive layer ICL1, the present disclosure is not limited thereto. For example, when the base insulating layer is further disposed between the first conductive layer ICL1 and the encapsulation layer TFE, the wavelength conversion layer WCLa may be disposed on the encapsulation layer TFE, and the first conductive layer ICL1 may be disposed on the base insulating layer. In an embodiment, both the first conductive layer ICL1 and the wavelength conversion layer WCLa may be disposed on the base insulating layer.

The wavelength conversion layer WCLa may overlap the second light receiving element OPD2 when viewed from above the plane. The wavelength conversion layer WCLa may convert the wavelength of light passing through the second dummy color filter DCF_R and may provide the converted light to the second light receiving element OPD2.

When the second light receiving element OPD2 is a green-type light receiving element that senses light in the green wavelength band, the wavelength conversion layer WCLa may convert light in the red wavelength band that passes through the second dummy color filter DCF_R into light in the green wavelength band.

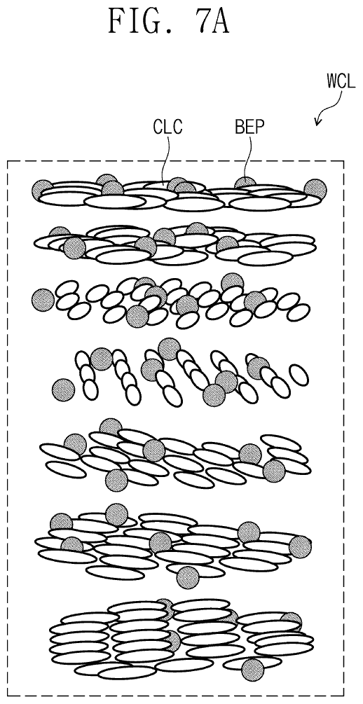

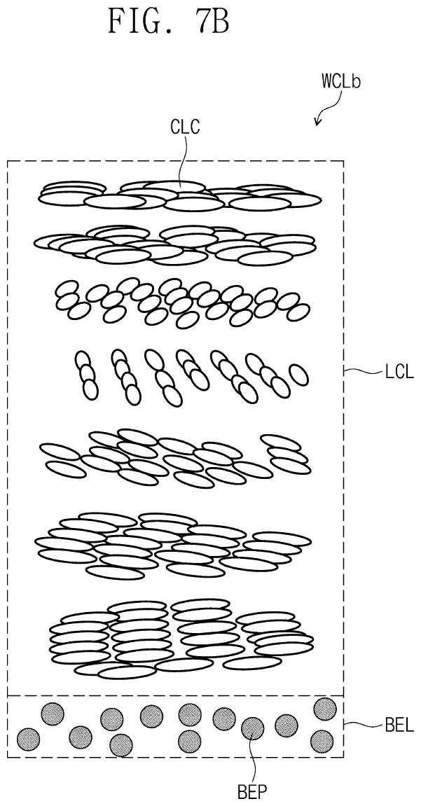

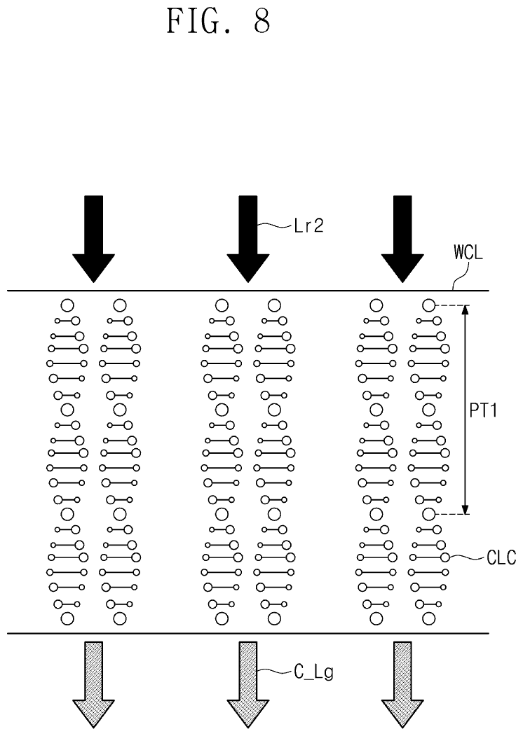

FIG. 7A is a view illustrating the wavelength conversion layer WCL according to an embodiment of the present disclosure. FIG. 7B is a view illustrating a wavelength conversion layer WCLb according to an embodiment of the present disclosure. FIG. 8 is a view illustrating the pitch of chiral liquid crystals included in a liquid crystal layer according to an embodiment of the present disclosure.

Referring to FIGS. 7A and 8, the wavelength conversion layer WCL may include the chiral liquid crystals CLC and luminance enhancement particles BEP. The wavelength conversion layer WCL may be a layer in which the chiral liquid crystals CLC are mixed with the luminance enhancement particles BEP.

The chiral liquid crystals CLC convert the second reflected light Lr2 into the first converted light C_Lg. In an embodiment of the present disclosure, the chiral liquid crystals CLC may include chiral tetraphenyl-ethylene-cholesterol (chiral TPE-Chol) crystals.

The wavelength of the first converted light C_Lg may be determined depending on the refractive index and the pitch PT1 of the chiral liquid crystals CLC. The wavelength of the first converted light C_Lg may increase as the pitch PT1 increases in a state in which the refractive index is fixed. That is, the pitch PT1 of the chiral liquid crystals CLC may be set such that the first converted light C_Lg has a green wavelength band. The chiral liquid crystals CLC may have a helical structure arranged while being twisted along a helical axis. Here, the pitch PT1 of the chiral liquid crystals CLC may be defined as a helical period and may be referred to as a helical pitch.

The luminance enhancement particles BEP may enhance (strengthen) the luminance of the first converted light C_Lg. The luminance enhancement particles BEP may include achiral quinoline-malononitrile (QM12). When compared to a structure including only the chiral liquid crystals CLC, the wavelength conversion layer WCL having the luminance enhancement particles BEP added thereto may increase the amount of the first converted light C_Lg, thereby improving the sensing sensitivity of the electronic device DD.

Referring to FIGS. 7B and 8, the wavelength conversion layer WCLb may include a liquid crystal layer LCL and a luminance enhancement layer BEL. The liquid crystal layer LCL may include chiral liquid crystals CLC, and the luminance enhancement layer BEL may include luminance enhancement particles BEP. The liquid crystal layer LCL converts the second reflected light Lr2 into the first converted light C_Lg using the chiral liquid crystals CLC. The luminance enhancement layer BEL may enhance (strengthen) the luminance of the first converted light C_Lg using the luminance enhancement particles BEP.

In an embodiment of the present disclosure, the luminance enhancement layer BEL may be disposed between the liquid crystal layer LCL and the second light receiving element OPD2 (refer to FIG. 4), and the liquid crystal layer LCL may be disposed between the luminance enhancement layer BEL and the second dummy color filter DCF_R (refer to FIG. 4).

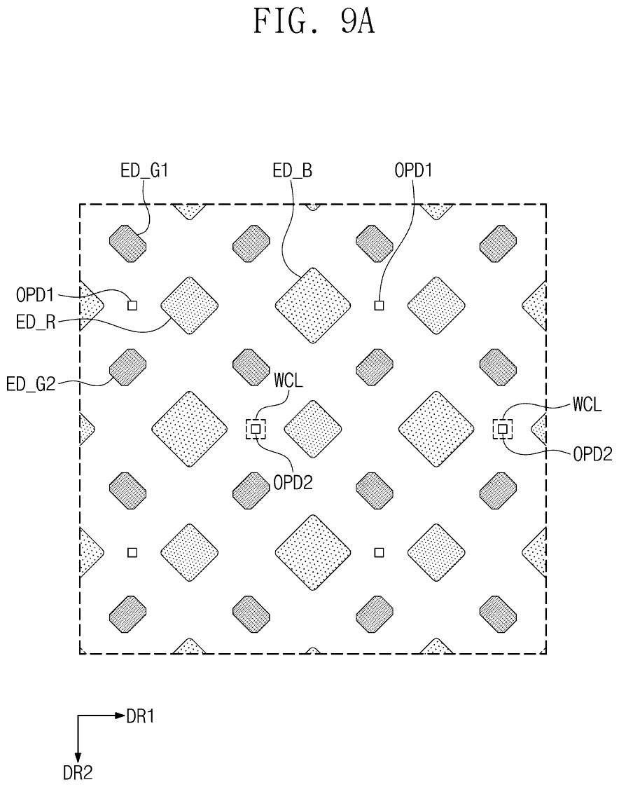

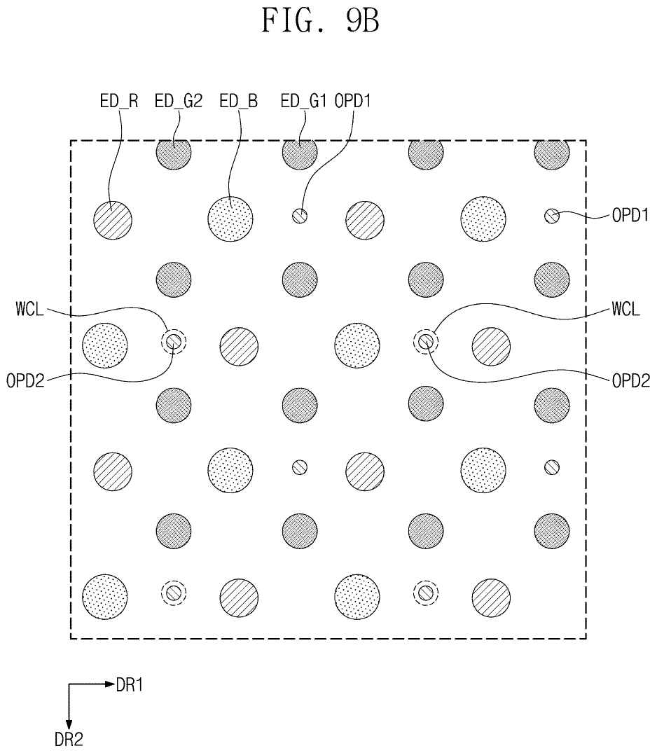

FIG. 9A is a plan view illustrating an arrangement relationship between light emitting elements, light receiving elements, and a wavelength conversion layer according to an embodiment of the present disclosure, and FIG. 9B is a plan view illustrating an arrangement relationship between light emitting elements, light receiving elements, and a wavelength conversion layer according to an embodiment of the present disclosure.

Referring to FIG. 9A, the element layer DP_ED (refer to FIG. 2) includes a plurality of light emitting elements ED_R, ED_G1, ED_G2, and ED_B and a plurality of light receiving elements OPD1 and OPD2.

The plurality of light emitting elements ED_R, ED_G1, ED_G2, and ED_B may be grouped into a plurality of reference units. In an embodiment of the present disclosure, each of the reference units may include four light emitting elements, that is, a first light emitting element ED_R (hereinafter, referred to as the red light emitting element), a second light emitting element ED_B (hereinafter, referred to as the blue light emitting element), and two third light emitting elements ED_G1 and ED_G2 (hereinafter, referred to as the first green light emitting element and the second green light emitting element). However, the number of light emitting elements included in each reference unit is not limited thereto. In an embodiment, each reference unit may include three light emitting elements, that is, a red light emitting element ED_R, a blue light emitting element ED_B, and a green light emitting element (one of the first green light emitting element ED_G1 and the second green light emitting element ED_G2).

In an embodiment of the present disclosure, the red light emitting element ED_R outputs light of the first color (e.g., red light), and the blue light emitting element ED_B outputs light of the second color (e.g., blue light) different from the light of the first color. Each of the first green light emitting element ED_G1 and the second green light emitting element ED_G2 outputs light of the third color (e.g., green light) that is different from the light of the first color and the light of the second color. The green light output from the first green light emitting element ED_G1 may have the same green wavelength band as the green light output from the second green light emitting element ED_G2.

The red light emitting elements ED_R and the blue light emitting elements ED_B may alternate with one another in the first direction DR1 and the second directions DR2. The first green light emitting elements ED_G1 and the second green light emitting elements ED_G2 alternate with one another in the first direction DR1 and the second direction DR2.

In an embodiment of the present disclosure, the red light emitting element ED_R may have a larger size than the first green light emitting element ED_G1 and the second green light emitting element ED_G2. In addition, the blue light emitting element ED_B may have a size greater than or equal to the size of the red light emitting element ED_R. The sizes of the light emitting elements ED_R, ED_G1, ED_G2, and ED_B are not limited thereto and may be modified in various ways. For example, in an embodiment of the present disclosure, the light emitting elements ED_R, ED_G1, ED_G2, and ED_B may be the same size.

The red and blue light emitting elements ED_R and ED_B, the first green light emitting element ED_G1, and the second green light emitting element ED_G2 may each have a polygonal shape (e.g., one of a rhombus shape, a square shape, a rectangular shape, a hexagonal shape, and an octagonal shape). The first green light emitting element ED_G1 and the second green light emitting element ED_G2 may have a shape different from those of the red and blue light emitting elements ED_R and ED_B. In an embodiment of the present disclosure, each of the red and blue light emitting elements ED_R and ED_B may have a rounded rhombus shape, and each of the first green light emitting element ED_G1 and the second green light emitting element ED_G2 may have an octagonal shape. The first green light emitting element ED_G1 and the second green light emitting element ED_G2 may have octagonal shapes extending in specific directions, respectively, and the extension direction of the first green light emitting element ED_G1 may cross (or, may be perpendicular to) the extension direction of the second green light emitting element ED_G2. The extension directions of the first green light emitting element ED_G1 and the second green light emitting element ED_G2 may be directions (e.g., diagonal directions) inclined with respect to the first direction DR1 and the second direction DR2.

One of the plurality of light emitting elements OPD1 and OPD2 may be disposed to correspond to each reference unit. However, the number of light emitting elements OPD1 and OPD2 disposed to correspond to each reference unit is not limited thereto. For example, two light receiving elements OPD1 and OPD2 may be disposed to correspond to each reference unit.

The plurality of light receiving elements OPD1 and OPD2 may include the first light receiving element OPD1 and the second light receiving element OPD2. In an embodiment of the present disclosure, each of the first light receiving element OPD1 and the second light receiving element OPD2 may be a green-type light receiving element that senses light in the green wavelength band. That is, the first light receiving element OPD1 and the second light receiving element OPD2 may be light receiving elements of the same type.

The first light receiving element OPD1 and the second light receiving element OPD2 are arranged in the first direction DR1 and the second direction DR2. Each of the first light receiving element OPD1 and the second light receiving element OPD2 is disposed between the red light emitting element ED_R and the blue light emitting element ED_B in the first direction DR1 and disposed between the first green light emitting element ED_G1 and the second green light emitting element ED_G2 in the second direction DR2.

In an embodiment of the present disclosure, each of the first light receiving element OPD1 and the second light receiving element OPD2 may have a shape that is the same as, or different from, the shape of each of the light emitting elements ED_G1, ED_G2, ED_R, and ED_B. In FIG. 9A, each of the first light receiving element OPD1 and the second light receiving element OPD2 has a square shape. However, the first light receiving element OPD1 and the second light receiving element OPD2 may have different polygonal shapes (e.g., a rhombus shape, a rectangular shape, a hexagonal shape, or an octagonal shape).

As illustrated in FIG. 9A, the first light receiving element OPD1 and the second light receiving element OPD2 may have the same shape and the same size. However, the present disclosure is not limited thereto. For example, the shape of the second light receiving element OPD2 may be different from the shape of the first light receiving element OPD1, and the size of the second light receiving element OPD2 may be greater than the size of the first light receiving element OPD1.

Each of the first light receiving element OPD1 and the second light receiving element OPD2 may have a size smaller than or equal to the sizes of the first green light emitting element ED_G1 and the second green light emitting element ED_G2. However, the sizes of the first light receiving element OPD1 and the second light receiving element OPD2 are not particularly limited and may be modified in various ways.

The wavelength conversion layer WCL may be disposed on the element layer DP_ED. The wavelength conversion layer WCL may overlap the second light receiving element OPD2 and may not overlap the first light receiving element OPD1. That is, the wavelength conversion layer WCL may be disposed to correspond to the second light receiving element OPD2.

In an embodiment of the present disclosure, the wavelength conversion layer WCL may have the same shape as the shape of the second light receiving element OPD2 when viewed from above the plane. That is, when the second light receiving element OPD2 has a square shape, the wavelength conversion layer WCL may also have a square shape. The wavelength conversion layer WCL may have a size greater than or equal to the size of the second light receiving element OPD2. However, the present disclosure is not limited thereto, and the wavelength conversion layer WCL may have a shape different from the shape of the second light receiving element OPD2. For example, when the second light receiving element OPD2 has a square shape, the wavelength conversion layer WCL may have a circular shape.

Referring to FIG. 9B, the red light emitting element ED_R, the blue light emitting element ED_B, the first green light emitting element ED_G1, and the second green light emitting element ED_G2 may each have a circular shape or an oval shape. The red light emitting element ED_R may have a larger size than the first green light emitting element ED_G1 and the second green light emitting element ED_G2. In addition, the blue light emitting element ED_B may have a size greater than or equal to the size of the red light emitting element ED_R. The sizes of the light emitting elements ED_R, ED_G1, ED_G2, and ED_B are not limited thereto and may be modified in various ways.

Each of the first light receiving element OPD1 and the second light receiving element OPD2 may have a shape that is the same as, or different from, the shape of each of the light emitting elements ED_G1, ED_G2, ED_R, and ED_B. In FIG. 9B, each of the first light receiving element OPD1 and the second light receiving element OPD2 has a circular shape. However, each of the first light receiving element OPD1 and the second light receiving element OPD2 may have various shapes such as a polygonal shape and an oval shape.

The first light receiving element OPD1 and the second light receiving element OPD2 may have the same shape and the same size. However, the present disclosure is not limited thereto. For example, the shape of the second light receiving element OPD2 may be different from the shape of the first light receiving element OPD1, and the size of the second light receiving element OPD2 may be greater than the size of the first light receiving element OPD1.

The wavelength conversion layer WCL may be disposed on the element layer DP_ED. The wavelength conversion layer WCL may overlap the second light receiving element OPD2 and may not overlap the first light receiving element OPD1. That is, the wavelength conversion layer WCL may be disposed to correspond to the second light receiving element OPD2.

In an embodiment of the present disclosure, the wavelength conversion layer WCL may have the same shape as the second light receiving element OPD2 when viewed from above the plane. That is, when the second light receiving element OPD2 has a circular shape, the wavelength conversion layer WCL may also have a circular shape. The wavelength conversion layer WCL may have a size greater than or equal to the size of the second light receiving element OPD2. However, the present disclosure is not limited thereto, and the wavelength conversion layer WCL may have a shape different from the shape of the second light receiving element OPD2. For example, when the second light receiving element OPD2 has a circular shape, the wavelength conversion layer WCL may have an oval shape or a polygonal shape.

The display module according to an embodiment may be applied to various electronic devices. An electronic device according to an embodiment may include the display module described above and may further include a module or device having other additional functions in addition to a display device.

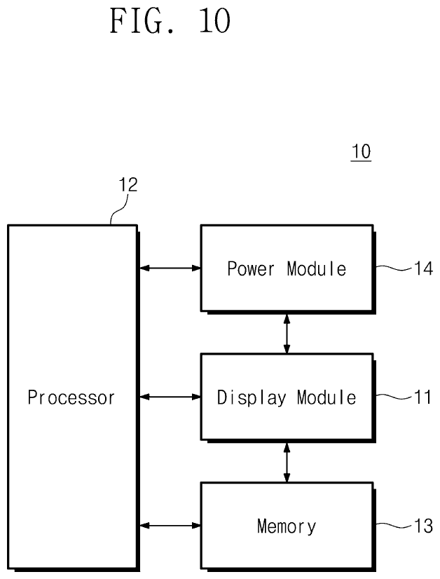

FIG. 10 is a block diagram of the electronic device according to an embodiment of the present disclosure.

Referring to FIG. 10, the electronic device 10 according to an embodiment may include a display module 11, a processor 12, a memory 13, and a power module 14.

The processor 12 may control operation of the display module 11 and may include at least one of a central processing unit (CPU), an application processor (AP), a graphic processing unit (GPU), a communication processor (CP), an image signal processor (ISP), and a controller. The processor 12 may include one or more processors. The one or more processors may be configured to operate individually, as a collective or as part of a collective. For example, two out of three processors in the device may operate together to execute an application.

Data information for operation of the processor 12 or the display module 11 may be stored in the memory 13. When the processor 12 executes an application stored in the memory 13, an image data signal and/or an input control signal may be transferred to the display module 11, and the display module 11 may process the provided signal and may output image information through a display screen.

The power module 14 may include a power supply module, such as a power adaptor or a battery device, and a power conversion module that converts power supplied by the power supply module and generates power for operation of the electronic device 10.

At least one of the components of the electronic device 10 described above may be included in the display module according to the embodiments described above. In addition, some of the separate modules functionally included in one module may be included in the display module, and the other separate modules may be provided separately from the display module. For example, the display module 11 may be included in the display device, and the processor 12, the memory 13, and the power module 14 may be provided in the form of other devices within the electronic device 10 rather than the display device.

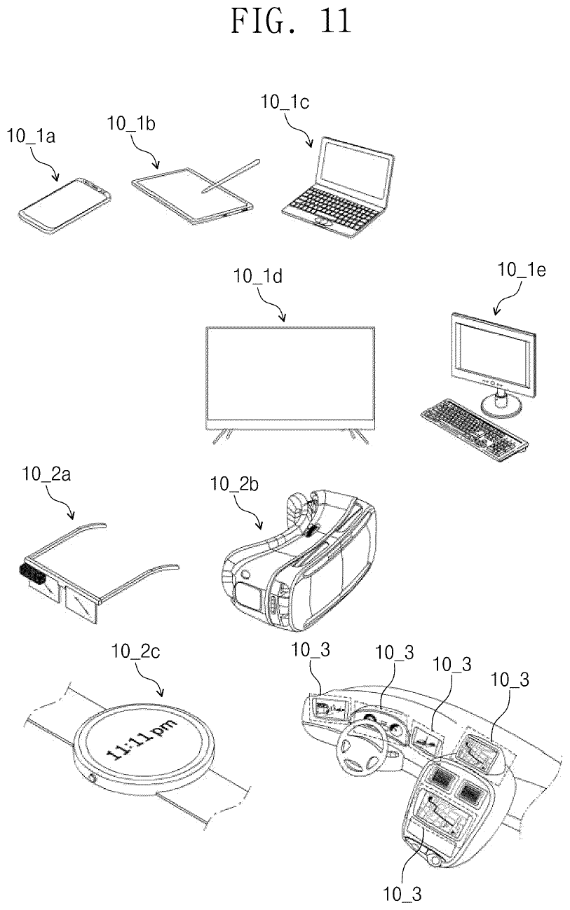

FIG. 11 illustrates schematic views of electronic devices according to various embodiments.

Referring to FIG. 11, the electronic devices according to the various embodiments, to which the display module is applied, may include not only an electronic device for displaying an image, such as a smart phone 10_1a, a tablet PC 10_1b, a laptop computer 10_1c, a TV 10_1d, or a desk monitor 10_1e, but also a wearable electronic device, such as smart glasses 10_2a, a head mounted display 10_2b, or a smart watch 10_2c, and a vehicle electronic device 10_3, such as a center information display (CID) or a room mirror display disposed on an instrument panel, a center fascia, and a dashboard of a vehicle.

As described above, the wavelength conversion layer may be disposed on some of the light receiving elements, and thus various pieces of biometric information may be sensed using only the light receiving elements of the same type.

In addition, since the light receiving elements of the same type are disposed, the light receiving elements may be disposed in the entire area of the display panel, and thus the display panel may sense biometric information in the entire area.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electronic device comprising:
a base layer including a display area and a non-display area;
a circuit layer disposed on the base layer;
an element layer disposed on the circuit layer, the element layer including light emitting elements and light receiving elements, each disposed in the display area; and
a wavelength conversion layer disposed on the element layer and configured to overlap some of the light receiving elements.

2. The electronic device of claim 1, wherein the light emitting elements include:
a first light emitting element configured to output first light in a first wavelength band; and
a second light emitting element configured to output second light in a second wavelength band different from the first wavelength band of the first light.

3. The electronic device of claim 2, wherein the wavelength conversion layer receives second reflected light generated by reflection of the second light and converts a wavelength of the second reflected light to output first converted light.

4. The electronic device of claim 3, wherein the light receiving elements include:
a first light receiving element configured to receive first reflected light generated by reflection of the first light; and
a second light receiving element configured to receive the first converted light, and
wherein the wavelength conversion layer overlaps the second light receiving element and does not overlap the first light receiving element.

5. The electronic device of claim 4, wherein the first light is light in a green wavelength band, and the second light is light in a red wavelength band, and
wherein each of the first reflected light and the first converted light is light in the green wavelength band.

6. The electronic device of claim 4, wherein the wavelength conversion layer includes:
a chiral liquid crystal configured to covert the second reflected light into the first converted light; and
a luminance enhancement particle configured to enhance luminance of the first converted light.

7. The electronic device of claim 4, wherein the wavelength conversion layer includes:
a liquid crystal layer including a chiral liquid crystal, the liquid crystal layer being configured to covert the second reflected light into the first converted light; and
a luminance enhancement layer disposed between the liquid crystal layer and the second light receiving element and configured to enhance luminance of the first converted light.

8. The electronic device of claim 4, further comprising:
a color filter layer disposed on the element layer,
wherein the color filter layer includes:
a first color filter configured to overlap the first light emitting element, the first color filter having a first color;
a second color filter configured to overlap the second light emitting element, the second color filter having a second color;
a first dummy color filter configured to overlap the first light receiving element, the first dummy color filter having the first color; and
a second dummy color filter configured to overlap the second light receiving element, the second dummy color filter having the second color.

9. The electronic device of claim 8, wherein the wavelength conversion layer is disposed between the second light receiving element and the second dummy color filter.

10. The electronic device of claim 8, further comprising:
an encapsulation layer disposed between the element layer and the color filter layer,
wherein the wavelength conversion layer is disposed between the element layer and the encapsulation layer.

11. The electronic device of claim 8, further comprising:
an encapsulation layer configured to cover the element layer; and
an input sensing layer disposed between the encapsulation layer and the color filter layer,
wherein the wavelength conversion layer is disposed between the encapsulation layer and the color filter layer.

12. The electronic device of claim 4, wherein the wavelength conversion layer has a shape corresponding to a shape of the second light receiving element.

13. An electronic device comprising:
a base layer including a display area and a non-display area;
a circuit layer disposed on the base layer;
an element layer disposed on the circuit layer, the element layer including a first light emitting element, a second light emitting element, a first light receiving element, and a second light receiving element, each disposed in the display area;
a color filter layer disposed on the element layer, the color filter layer including a first color filter and a second color filter configured to overlap the first light emitting element and the second light emitting element, respectively, and a first dummy color filter and a second dummy color filter configured to overlap the first light receiving element and the second light receiving element, respectively; and
a wavelength conversion layer disposed between the second light receiving element and the second dummy color filter.

14. The electronic device of claim 13, wherein the first light emitting element outputs first light in a first wavelength band,
wherein the second light emitting element outputs second light in a second wavelength band different from the first wavelength band of the first light, and
wherein the wavelength conversion layer receives second reflected light generated by reflection of the second light and converts a wavelength of the second reflected light to output first converted light.

15. The electronic device of claim 14, wherein the first light receiving element receives first reflected light generated by reflection of the first light,
wherein the second light receiving element receives the first converted light, and
wherein the wavelength conversion layer overlaps the second light receiving element and does not overlap the first light receiving element.

16. The electronic device of claim 15, wherein the first light is light in a green wavelength band, and the second light is light in a red wavelength band, and
wherein each of the first reflected light and the first converted light is light in the green wavelength band.

17. The electronic device of claim 13, further comprising:
an encapsulation layer disposed between the element layer and the color filter layer,
wherein the wavelength conversion layer is disposed between the element layer and the encapsulation layer.

18. The electronic device of claim 13, further comprising:
an encapsulation layer configured to cover the element layer; and
an input sensing layer disposed between the encapsulation layer and the color filter layer,
wherein the wavelength conversion layer is disposed between the encapsulation layer and the color filter layer.

19. The electronic device of claim 13, wherein the wavelength conversion layer has a shape corresponding to a shape of the second light receiving element.

20. The electronic device of claim 13, wherein the wavelength conversion layer includes a chiral liquid crystal.
